(19) United States
(12) Patent Application Publication
(10) Pub. No.: US 2026/0363102 A1
(43) Pub. Date: Nov. 12, 2026

(54) SUBSTRATE-IN-SUBSTRATE MODULE EMBEDDING FOR HIGH POWER PACKAGES

(71) Applicant: Advanced Micro Devices, Inc., Santa Clara, CA (US)

(72) Inventors: Prithwish CHATTERJEE, Austin, TX (US); Robert Grant SPURNEY, Austin, TX (US); Sri Ranga Sai BOYAPATI, Austin, TX (US); Prahalad MURALI, Austin, TX (US); Raja SWAMINATHAN, Austin, TX (US); Deepak Vasant KULKARNI, Austin, TX (US); William James LAMBERT, Phoenix, AZ (US); Xiaoqian LI, Santa Clara, CA (US)

(21) Appl. No.: 19/425,717

(22) Filed: Dec. 18, 2025

Related U.S. Application Data
(60) Provisional application No. 63/801,639, filed on May 7, 2025.

(51) Int. Cl. H10W 70/60; H10W 70/05; H10W 70/63; H10W 70/68; H10W 90/10

(52) U.S. Cl. CPC H10W 70/614; H10W 70/05; H10W 70/635; H10W 70/682; H10W 90/10

(57) ABSTRACT

Integrated circuit (IC) modules having one or more IC devices embedded into a substrate core are provided, along with electronic devices and chip packages having the same. Also provided are method for fabricating the IC module. In one example, the IC module includes an inner substrate core, an outer substrate core, and one or more IC devices. The inner substrate core includes a cavity in which the one or more IC devices mounted. The outer substrate core includes a cavity in which the inner substrate core is mounted.

### CROSS REFERENCE TO RELATED APPLICATIONS

This application claims benefit of United States Provisional Patent Application No. 63/801,639, filed May 7, 2025, which is incorporated by reference in its entirety.

### TECHNICAL FIELD

Embodiments of the present disclosure generally relate to embedding one or more integrated circuit (IC) devices into a substrate core, and chip packages having the same. In particular, embodiments relate to one or more IC devices disposed a cavity extending through the substrate core, chip packages having the same.

### BACKGROUND

Data center graphic and central processing units have seen power consumption recently increase from 550-750 watts to 2.5 kilowatts, and is expected to approach or exceed 5 kilowatts in the not so distant future. This increase in power density requires the development of advanced solutions to manage the heightened electrical and thermal loads effectively. To assist meeting electrical and thermal load challenges, Integrated Voltage Regulators (IVR) are used as they support dynamic voltage scaling. This feature allows processors to adjust voltage levels in real-time based on workload demands, optimizing power consumption during low activity periods while enhancing performance during peak operations.

However, embedding active and passive components present substantial challenges. Industry trends currently demand that embedded components precisely match the core thickness, requiring intricate and precise design and manufacturing techniques.

Looking forward, greater computational power with larger and more complex die designs will demand a substantial increase in the number of integrated voltage regulators required. This drives the necessity to address warpage challenges by using substrates with thicker cores while maintaining component compatibility. However, current state of the art cores are generally limited to a thickness of about 750 µm, above which, warpage and reliability challenges make commercial adoption unreasonable.

### SUMMARY

Disclosed herein is a dual-substrate (e.g., substrate-in-substrate) package architecture that enhances power delivery and component integration. This unique architecture features a core (i.e., inner) substrate with embedded components. The core substrate integrates at least one or both of active and passive components. The active and passive components including silicon elements, like integrated voltage regulators, as well as inductors and capacitors. The core substrate is disposed in a cavity formed in an outer substrate. In some examples, the core substrate may be disposed towards the top surface of the outer substrate, with allows active elements to be positioned closer to the die, improving electrical performance and efficiency.

The adaptive layered package architecture can be embodied in integrated circuit (IC) modules having one or more IC devices embedded into a substrate core are provided, along with electronic devices and chip packages having the same. In one example, the IC module includes an inner substrate core, an outer substrate core, and one or more IC devices. The inner substrate core includes a cavity in which the one or more IC devices mounted. The outer substrate core includes a cavity in which the inner substrate core is mounted.

Also provided are method for fabricating an IC module having adaptive layered package architecture.

In one example, an integrated circuit (IC) module is provided that includes a substrate core, an IC device module, upper built-up layers, and lower built-up layers. The substrate core includes a cavity open through first and second faces of the substrate core. The IC device module is disposed in the cavity and includes one or more IC devices, upper module built-up layers, and lower module built-up layers. The upper and lower module built-up layers have circuitry coupled to the one or more IC devices. The lower module built-up layers are separated from the upper module built-up layers by the plurality of IC devices. The upper built-up layers are formed on the IC device module and the first face of the substrate core while the lower built-up layers are formed on the IC device module and the second face of the substrate core. The upper built-up layers have circuitry coupled to the upper module built-up layers and circuitry routed through the substrate core. The lower built-up layers have circuitry coupled to the lower module built-up layers and the circuitry routed through the substrate core.

In another example, an integrated circuit (IC) module includes a first assembly separated from a second assembly by a sacrificial carrier. The first assembly includes a first IC device module disposed in a cavity of a first substrate core, the cavity formed in the first substrate core and open through first and second faces of the first substrate core. The first IC device module includes one or more first IC devices, upper module built-up layers, and lower module built-up layers. The upper and lower module built-up layers have circuitry coupled to the one or more first IC devices. The upper and lower module built-up layers are separated by the one or more first IC devices. Upper built-up layers are formed on the first IC device module and the first face of the first substrate core. The upper built-up layers have circuitry coupled to the upper module built-up layers and circuitry routed through the first substrate core. The second assembly includes a second IC device module disposed in a cavity of a second substrate core. The second IC device module includes one or more second IC devices, upper module built-up layers having circuitry coupled to the one or more second IC devices, and lower module built-up layers having circuitry coupled to the one or more second IC devices. The lower module built-up layers are separated from the upper module built-up layers by the one or more second IC devices. The upper built-up layers are formed on the second IC device module and the first face of the second substrate core. The upper built-up layers have circuitry coupled to the upper module built-up layers and circuitry routed through the second substrate core.

In yet another example, an integrated circuit (IC) substrate is provided. The IC substrate includes a main core, an IC device module and first built-up layers. The main core has a first face, a second face, and a main core cavity. The main core cavity is open through the first and second faces of the main core. The IC device module is disposed in the main core cavity and includes module core and one or more IC devices. The module core has a module cavity in which the one or more IC devices are disposed. The module core has a thickness that is less than a thickness of the main core. The first built-up layers are formed on the IC device module and the first face of the main core. The first built-up layers have circuitry coupled to circuitry of the one or more IC devices.

In still another example, a chip package is provided. The chip package includes a main core, an IC device module and first built-up layers, an integrated circuit (IC) die. The main core has a first face, a second face, and a main core cavity. The main core cavity is open through the first and second faces of the main core. The IC device module includes a module core and one or more IC devices. The module core has a thickness that is less than a thickness of the main core. The one or more IC devices are embedded in mold compound filling in the module cavity. The first built-up layers are formed on the IC device module and the first face of the main core. The IC die has functional circuitry coupled to the one or more IC devices through circuitry of the first built-up layer routing.

In still another example, a chip package is provided. The chip package includes a main core, an IC device module and first built-up layers, an integrated circuit (IC) die. The main core has a first face, a second face, and a main core cavity. The main core has a thickness of greater than about 1000 µm. The main core cavity is open through the first and second faces of the main core. The IC device module is disposed in the main core cavity and includes a module core, first module built-up layers, second module built-up layers, filler layers, and one or more IC devices. The module core has a thickness that is less than or equal to about 750 µm. The one or more IC devices are embedded in mold compound filling in the module cavity. The first module built-up layers are disposed in the main core cavity in and are in contact with the mold compound. The second module built-up layers are disposed in the main core cavity and are in contact with the mold compound. The first filler layers are disposed in the main core cavity and are in contact with the second module built-up layers. The first filler layer have first filler layer circuitry that is coupled to the one or more IC devices through circuitry of the second module built-up layers. The first built-up layers are formed on the IC device module and the first face of the main core. The IC die is disposed on the first built-up layers. The IC die has functional circuitry that is coupled to the one or more IC devices through circuitry of the first built-up layer.

### BRIEF DESCRIPTION OF THE DRAWINGS

So that the manner in which the above recited features of the present invention can be understood in detail, a more particular description of the invention, briefly summarized above, may be had by reference to examples, some of which are illustrated in the appended drawings. It is to be noted, however, that the appended drawings illustrate only typical examples of this invention and are therefore not to be considered limiting of its scope, for the invention may admit to other equally effective examples.

FIGS. 1 and 2 illustrate a comparison between substrates having traditional architecture and a substrate-in-substrate architecture having embedded IC devices.

FIG. 3 is a schematic section view of an inner substrate module having embedded IC devices.

FIG. 4 is a schematic section view of another inner substrate module having embedded IC devices.

FIG. 5 is a schematic section view of an electronic device that includes a chip package having a substrate-in-substrate architecture having embedded IC devices.

FIG. 6 is a block diagram of one example of a method for forming an inner substrate module.

FIGS. 7A-7G are schematic sectional views of an inner substrate module during different stages of fabrication.

FIG. 8 is a block diagram of another example of a method for forming an inner substrate module.

FIGS. 9A-9H are schematic sectional views of an inner substrate module during different stages of fabrication.

FIG. 10 is a high level schematic diagram of one example of a method for forming substrate-in-substrate structures.

FIG. 11 is a block diagram of one example of a method for forming a substrate having an inner substrate module embedded in a main core.

FIGS. 12A-12D are schematic sectional views of a substrate having an inner substrate module embedded in a main core during different stages of fabrication.

To facilitate understanding, identical reference numerals have been used, where possible, to designate identical elements that are common to the figures, and a lower-case letter added where the elements are substantially the same. It is contemplated that elements of one embodiment may be beneficially incorporated in other embodiments.

### DETAILED DESCRIPTION

Disclosed herein is a dual-substrate (e.g., substrate-in-substrate) architecture that enhances power delivery and component integration. This unique architecture includes a core substrate with embedded components. The core substrate is disposed in a cavity formed in an outer substrate. The first substrate integrates both active and passive components, including silicon elements like integrated voltage regulators, as well as inductors and capacitors. In some embodiments, this configuration allows active elements to be positioned closer to the die, improving electrical performance and efficiency.

The dual-substrate may be fabricated using an innovative peelable core technology. A peelable or sacrificial core is employed to construct asymmetric or adaptive layered structures. This technique enables precise layering and the accommodation of complex component configurations, further optimizing power delivery and enhancing substrate functionality.

The dual-substrate architecture also provides enhanced mechanical stability. The dual-substrate architecture includes an outer substrate that has a second, or inner, substrate disposed therein. The outer substrate is thicker than the inner substrate, which not only supports additional integrated components, but also mitigates warpage risks, ensuring reliability and durability in high-performance applications.

The dual-substrate architecture delivers significant improvements in packaging performance by focusing on closer integration and efficient power delivery while maintaining structural integrity.

In one example, IC component are on separate substrates using a sacrificial core to attach a pre-patterned core with cavities for component placement. A built-up process is formed on the attached components to increase thickness and fan out interconnections. After the initial built-up, the substrate is de-paneled and the sacrificial core removed, resulting in a fully functional module which ready for further processing (i.e., assembly into a larger structure) from a handling perspective. If necessary, add additional layers on the backside of substrate 1 to enhance thickness or functionality.

The fabricated modules (combination of multiple substrates) are singulated and embedded into a primary (i.e., outer/main) substrate having a thicker core as compared to the height of the inner substrate. The module formed from the substrate with embedded IC components is embedded in a thicker, outer main substrate, which facilitates two-sided connection for embedded components.

In some examples, the inner substrate is embedded asymmetrically such the inner substrate and it’s embedded IC devices are much closer to the IC die side of the outer substrate. The asymmetric location of the embedded IC devices results in shorter routing to the IC die, thus improving performance. Embedding an asymmetric substrate into the core of another substrate also addresses several critical challenges in the realm of advanced computing systems, such as independent core and substrate scaling, improved power delivery, cost and capacity optimization, enhanced testing capability, capacity benefits, and ESD control.

Independent core and substrate scaling is enabled by the integration of a thicker core designed specifically to address warpage issues, along with a thinner substrate for embedding components, all while utilizing advanced routing techniques. This flexibility allows each layer to be optimized independently, enhancing structural integrity and performance.

Improved power delivery is achieved by positioning embedded components closer to the top die, this approach improves power delivery efficiency. The proximity facilitates better electrical connectivity and reduces latency, effectively overcoming power delivery challenges prevalent in high-density designs.

Cost and capacity optimization leverages the ability to construct two modules within a single substrate significantly enhances the capacity for embedding components. This dual-module construction not only increases the number of components that can be embedded in the inner substrate, but also optimizes cost constraints associated with such a complex assembly process.

Enhanced testing capability is provided as the structure allows for the independent testing of the first module, ensuring that only known-good die complexes are integrated into the final substrate. This step enhances reliability and confidence in the final product, reducing the risk of defects and failures.

Capacity benefits are achieve via this scalable solution, which accommodates the growing demands for integrated components without compromising the substrate's structural or functional integrity.

ESD control is improved as the novel structure disclosed herein provides tighter control over electrostatic discharge (ESD), further safeguarding sensitive components and ensuring long-term reliability and performance of the assembled modules.

Overall, this embedding strategy provides significant advancements in managing the complexity and demands of next-generation computing systems, balancing performance, capacity, and cost with innovative engineering solutions.

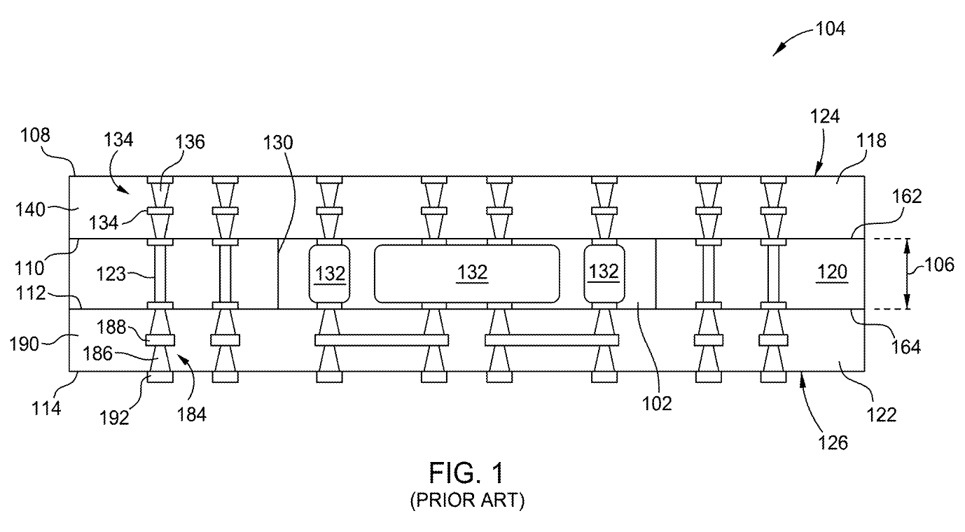

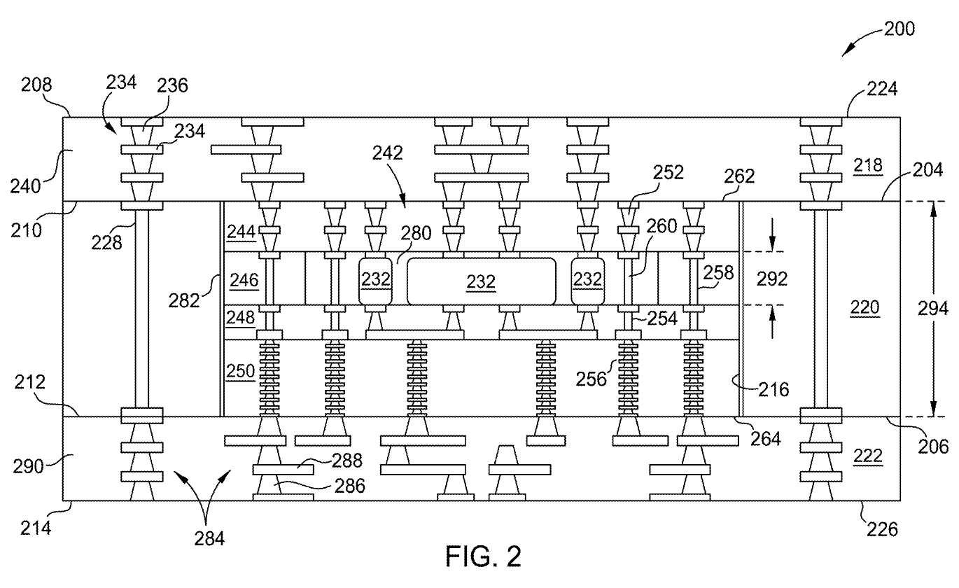

FIGS. 1 and 2 illustrate a comparison between traditional substrate architecture and the novel substrate-in-substrate architecture developed by the inventors. Referring first to FIG. 1, a schematic side view one example of a conventional substrate 104 is illustrated. The substrate 104 depicted in FIG. 1 is configured as a package substrate. However, the substrate 104 may also be configured an interposer disposed between a package substrate and one or more integrated circuit (IC) dies (not shown in FIG. 1).

The substrate 104 includes a first built-up layer 118, a core 120, and a second built-up layer 122. The core 120 is sandwiched between the first and second built-up layers 118, 122. The substrate 104 has a first face 124 and a second face 126. The first face 124 of the substrate 104 is configured to be connected to one or more IC dies. A first face 108 of the first built-up layer 118 forms the first face 124 of the substrate 104, while the opposite side of the first built-up layer 118 has a second face 110 that is disposed in contact with a first face 162 of the core 120. The second face 126 of the substrate 104 is configured to be connected to a printed circuit board (PCB). Similarly, a first face 112 of the second built-up layer 122 is disposed in contact with a second face 164 of the core 120, while the opposite side of the second built-up layer 122 has a second face 114 that forms the second face 126 of the substrate 104.

The core 120 of the substrate 104 are generally formed from an inorganic material, such as silicon, ceramic, glass reinforced plastic, and the like. The core 120 of the substrate 104 may alternatively be formed from other rigid materials. The core 120 as a thickness 106 defined first face 162 and a second face 164. Generally, current technology limits the thickness 106 of the core 120 to about 750 µm, above which, warpage becomes problematic, making reliability a liability.

The core 120 includes a cavity 130. The cavity 130 extends from the first face 162 and exits the second face 164 of the core 120, thus forming a passage completely through the core 120. One or more integrated circuit (IC) devices 132 are disposed in the cavity 130. The IC device 132 may be a passive or active IC device. Example of passive and active IC devices used in convention substrates include integrated voltage regulator (IVR), an integrated passive device (IPD), inductor, a capacitor, a resistor, a diode, power management module, power cell device, or other solid state device.

A plurality of vias 128 are disposed through the core 120. The vias 128 are filled with a conductive material, such as copper. Although only a few vias 128 are illustrated in the core 120 depicted in FIG. 1, it is to be understood the core 120 may include many vias 128.

The first built-up layer 118 generally includes patterned metal layers formed between dielectric layers 140. Although the dielectric layers 140 are illustrated in FIG. 1 as a single block of material, at least 3 or more layers of dielectric material comprise the dielectric layers 140 of the first built-up layer 118. The patterned metal layers are interconnected to form first built-up layer routing circuitry 134. The first built-up layer routing circuitry 134 is generally formed by vias 136 and lines 138. The first built-up layer routing circuitry 134 generally terminates at a contact pad exposed on the first face 124 of the substrate 104.

The first built-up layer routing circuitry 134 may be coupled to the vias 128 formed through the core 120 to provide ground, power, and/or signals through the first built-up layer 118 to one or more IC dies mounted on the substrate 104. The first built-up layer routing circuitry 134 is also coupled to the IC devices 132 disposed in the core 120 to provide ground, power, and/or signals to and/or from the IC devices 132.

The second built-up layer 122 generally includes patterned metal layers formed between dielectric layers 190. Although the dielectric layers 190 are illustrated in FIG. 1 as a single block of material, at least 3 or more layers of dielectric material comprise the dielectric layers 190 of the second built-up layer 122. The patterned metal layers are interconnected to form second built-up layer routing circuitry 184. The second built-up layer routing circuitry 184 is generally formed by vias 186 and lines 188. One end of the second built-up layer routing circuitry 184 is connected to the vias 128 formed through the core 120 of the substrate 104. The second built-up layer routing circuitry 184 may be coupled to the first built-up layer routing circuitry 134 through the vias 128 formed through the core 120 to provide ground, power, and/or signals through the substrate 104 to the functional circuitry of a subsequently attached IC die. One end of the second built-up layer routing circuitry 184 may optionally terminate and be coupled to the circuit elements (e.g., the active and/or passive devices) of the IC device 132. The other end of the second built-up layer routing circuitry 184 terminates at a contact pad 192 exposed on the second face 126 of the substrate 104. The contact pad 192 is utilized to connect the substrate 104 to a printed circuit board (PCB).

As discussed above, integrating active and passive components, including voltage regulators and inductors, presents significant challenges due to the core thickness limitation of about 750 µm. With larger and more complex die designs on the horizon, it is expected that a substantial increase in the number of integrated voltage regulators will be needed, which will significantly reduce the substrate stiffness and promote warpage. Warpage across a large substrate places all solder connections at a significant risk, thus making the finished IC device more susceptible to failure and reducing service life.

The inventors have recognized that new innovations, such as embedding components within the substrate will help mitigate these demands. Accordingly, the inventors have developed a novel substrate-in-substrate architecture that meets the challenges brought on by the complexity of large die designs, particular where the number of embedded components may reach into the hundreds. The novel substrate-in-substrate architecture provides a scalable and economical solution, providing durability against warpage while meeting the demanding power density and integration requirements needed for advanced computing systems.

The substrate-in-substrate architecture beneficially reduces the overall layer count for substrate, which results in yield improvement, complexity reduction, cost reduction, and capacity use reduction. Additionally, testing the IC device module fabricated in the inner substrate prior to insertion in the outer substrate provided additional yield improvements.

The substrate-in-substrate architecture also introduces several novel features that enhance the functionality and versatility of advanced computing substrates. These include asymmetric stack-up capability, dual-module integration, comprehensive pre-embedding testing, and full vertical connectivity. Asymmetric stack-up capability allows for an asymmetric stack-up in the final substrate, enabling the use of different materials on the front and back of the core. This flexibility is important for mitigating warpage in the module, providing a tailored approach to manage thermal and mechanical stresses effectively.

Dual-module integration leverages a sacrificial core to allows for the creation of two substrate modules from a single substrate. This innovative process not only optimizes material use but also enhances integration efficiency, enabling more complex and dense configurations.

Comprehensive pre-embedding testing is the ability to perform full testing of a module containing the IC devices before embedding the module into the substrate. Comprehensive pre-embedding testing ensures that only fully functional and reliable die complexes are used. This feature significantly improves the quality and reliability of the final product by reducing the risk of integrating defective components.

Full vertical connectivity between substrate modules allows seamless electrical and signal integration across the layers of the substrate-in-substrate structure. This connectivity enhances performance by reducing signal loss and improving data transfer efficiency within the stacked modules.

These novel features collectively provide a robust and flexible approach to addressing the challenges of modern electronic component integration, resulting in improved performance and reliability of advanced computing systems.

One example of a substrate-in-substrate architecture for a substrate 200 suitable for use in chip packaging is illustrated in the schematic sectional view of FIG. 2. The substrate 200 includes a module core 246 embedded in a main core 220. The module core 246 has one or more integrated circuit (IC) devices 232 embedded therein. The module core 246 has a thickness 192 that is generally selected to be about the same height of the IC devices 232 embedded the module core 246. The main core 220 has a thickness 294 that is greater than a thickness 292 of the module core 246. The thickness 294 of the main core 220 is selected to provide good stiffness and warpage resistance.

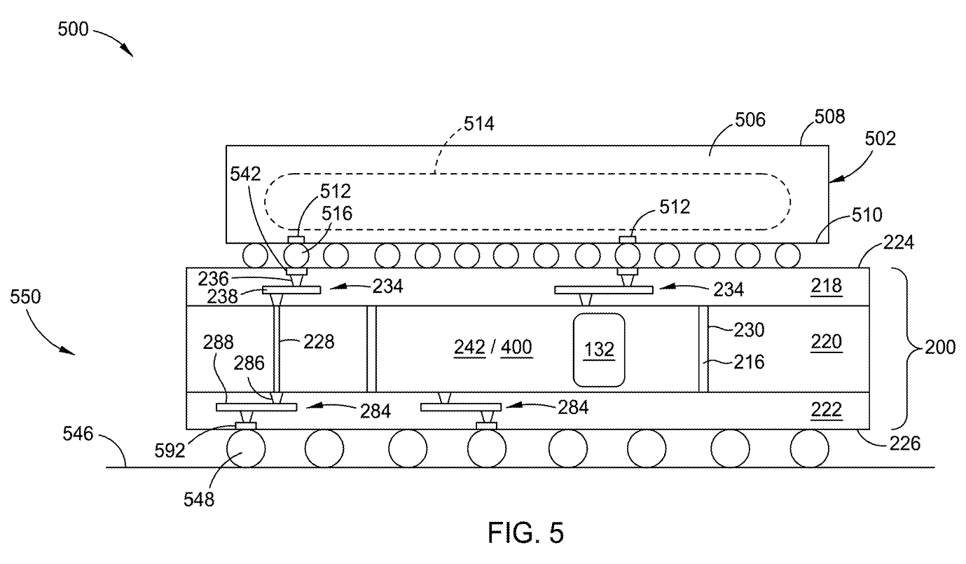

The substrate 200 depicted in FIG. 2 is configured as a package substrate. However, the substrate 200 may also be configured an interposer disposed between a package substrate and one or more integrated circuit (IC) dies (as later shown in FIG. 5).

Continuing to refer to FIG. 2, the module core 246 is part of an inner substrate module 242. The inner substrate module 242 can be prefabricated and tested assembly that is subsequently disposed in a cavity 230 formed in the main core 220. The inner substrate module 242 is retained in the cavity 230 of the main core 220 using an adhesive 216. The adhesive 216 may be an epoxy, mold compound or other adhesive suitable for packaging applications. The inner substrate module 242 is described in detail further below.

Turning first to the overall architecture of the substrate 200, the substrate 200 includes a first built-up layer 218, the main core 220, and a second built-up layer 222. The substrate 200 has a first face 224 and a second face 226. The first face 224 is configure to connect with one or more integrated circuit (IC) dies. A first face 208 of the first built-up layer 218 forms the first face 224 of the substrate 200, while second face 210 of the first built-up layer 218 is disposed in contact with a first face 204 of the main core 220. Similarly, a first face 212 of the second built-up layer 222 is disposed in contact with a second face 206 of the main core 220, while a second face 214 of the second built-up layer 222 forms the second face 226 of the substrate 200.

The main core 220 of the substrate 200 is generally formed from an inorganic material, such as silicon, ceramic, glass reinforced plastic, and the like. The main core 220 of the substrate 200 may alternatively be formed from other rigid materials. The first built-up layer 218 is disposed on the first face 204 of the main core 220. The second built-up layer 222 is disposed in contact with the second face 206 of the main core 220.

A cavity 230 is formed in the main core 220. The cavity 230 may be in the form of a cavity that extends from the first face 204 into the main core 220. In the example depicted in FIG. 2, the cavity 230 extends from the first face 204 and exits the second face 206 of the main core 220, thus forming a passage completely through the main core 220.

The inner substrate module 242 that includes the IC devices 232 is disposed in the cavity 230. The inner substrate module 242 does not extend beyond the faces 204, 206 of the main core 220. In one example, the inner substrate module 242 is a pre-fabricated unitary component that secured in the cavity 230, for example by using the adhesive 216.

As mentioned above, the thickness 292 of the inner substrate module 242 is less than the thickness 294 of the main core 220. In one example, the thickness 292 of the inner substrate module 242 is less than or equal to about 750 µm. In another example, the thickness of the main core 220 is greater than about 750 µm. In another example, the thickness of the main core 220 is greater than about 1000 µm. In another example, the thickness of the main core 220 is greater than or equal to about 1400 µm, such as greater than 1700 µm. Similarly, the IC device 232 that is embedded in the module core 246 of the inner substrate module 242 has a height that is substantially the same as or less than the thickness 292 of the inner substrate module 242.

Continuing to refer to FIG. 2, a plurality of vias 228 are disposed through the main core 220. The vias 228 are filled with a conductive material, such as copper. Although only two vias 228 are illustrated in the main core 220 depicted in FIG. 2, it is to be understood that the main core 220 includes many vias 228. The vias 228 may be laser drilled or formed using another suitable technique. The vias 228 may be utilized to transmit/connect ground, power, and/or signals through the main core 220, and are ultimately coupled to the functional circuitry of the IC dies secured to the first face 224 of the substrate 200. In other examples, one or more of the vias 228 may be configured as thermally conductive pillars, such as copper or other metal pillars, whose primarily function is to transmit heat through the main core 220. Such vias 228 configured as thermally conductive pillars are not coupled to the functional circuitry of the IC dies subsequently mounted on the substrate 200.

The first built-up layer 218 generally includes patterned metal layers formed between dielectric layers 240. Although the dielectric layers 240 are illustrated in FIG. 2 as a single block of material, at least 3 or more layers of dielectric material comprise the dielectric layers 240 of the first built-up layer 218. The patterned metal layers are interconnected to form first built-up layer routing circuitry 234. The first built-up layer routing circuitry 234 is generally formed by vias 236 and lines 238. The first built-up layer routing circuitry 234 generally terminates at a contact pad exposed on the first face 224 of the substrate 200 that is utilized to connect to an IC die or other device.

The first built-up layer routing circuitry 234 may be coupled to the vias 228 formed through the main core 220 to provide ground, power, and/or signals through the first built-up layer 218 to the functional circuitry of the IC dies later mounted on the substrate 200. The first built-up layer routing circuitry 234 may optionally be utilized to couple to the vias 228 configured as heat transfer pillars to route heat out of the substrate 200. The first built-up layer routing circuitry 234 is also coupled to circuitry of the inner substrate module 242 and the IC devices 232 disposed therein to provide ground, power, and/or signals between the IC devices 232.

The second built-up layer 222 generally includes patterned metal layers formed between dielectric layers 290. Although the dielectric layers 290 are illustrated in FIG. 2 as a single block of material, at least 3 or more layers of dielectric material comprise the dielectric layers 290 of the second built-up layer 222. The patterned metal layers are interconnected to form second built-up layer routing circuitry 284. The second built-up layer routing circuitry 284 is generally formed by vias 286 and lines 288. One end of the second built-up layer routing circuitry 284 is connected to the vias 228 formed through the main core 220 of the substrate 200. The second built-up layer routing circuitry 284 may be coupled to the first built-up layer routing circuitry 234 through the vias 228 formed through the main core 220 to provide ground, power, and/or signals through the substrate 200 to the functional circuitry of the IC dies later mounted on the substrate 200. One end of the second built-up layer routing circuitry 284 may optionally terminate and be coupled to the circuit elements (e.g., the active and/or passive devices) of the IC device 232. The other end of the second built-up layer routing circuitry 284 terminates at a contact pad exposed on the second face 226 of the substrate 200 that is utilized to connect the substrate 200 to a printed circuity board (PCB).

The inner substrate module 242 disposed in the cavity 230 of the main core 220 generally includes a first module built-up layer 244, the module core 246, a second module built-up layer 248, and a filler layer 250. The module core 246 is sandwiched between the first module built-up layer 244 and the second module built-up layer 248.

The module core 246 includes vias 258 and a cavity 282 in which the IC devices 232 are embedded. The IC devices 232 may be secured in the cavity 282 of the module core 246 using a mold compound 280. The first module built-up layer 244 includes first module built-up layer routing circuitry 252. The second module built-up layer 248 is sandwiched between the module core 246 and the filler layer 250. The second module built-up layer 248 includes second module built-up layer routing circuitry 254. The filler layer 250 includes filler routing circuitry 256. The inner substrate module 242 includes a first face 262 and a second face 264. The first face 262 of the inner substrate module 242 connects the second face 210 of the first built-up layer 218. The second face 264 of the inner substrate module 242 is in contact with the first face 212 of the second built-up layer 222.

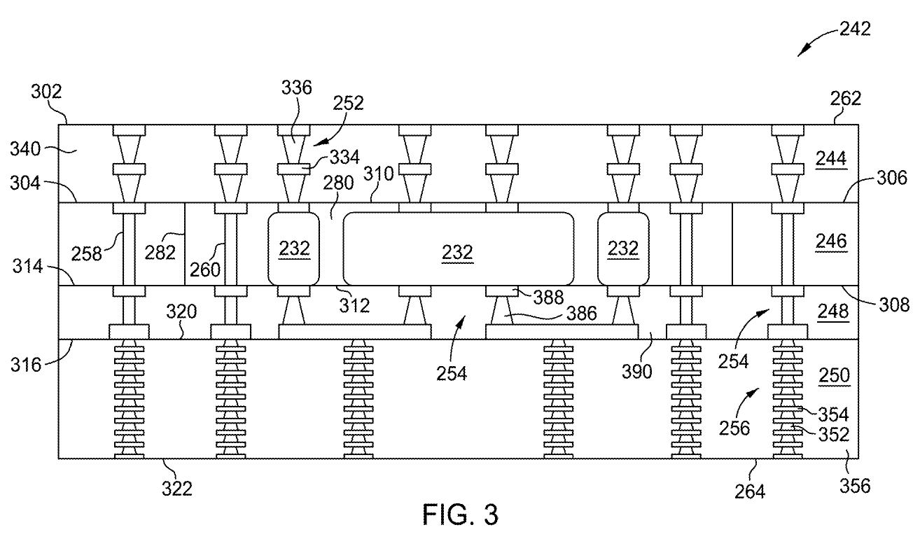

FIG. 3 is a schematic sectional view of one example of the inner substrate module 242. The first module built-up layer 244 of the inner substrate module 242 includes a first face 302 and a second face 304. The first face 302 of the first module built-up layer 244 connects the second face 210 of the first built-up layer 218. The second face 304 of the first module built-up layer 244 is in contact with a first face 306 of the module core 246.

The first module built-up layer 244 generally includes patterned metal layers formed between dielectric layers 340. Although the dielectric layers 340 are illustrated in FIG. 3 as a single block of material, at least 2 or more layers of dielectric material comprise the dielectric layers 340 of the first module built-up layer 244. The patterned metal layers are interconnected to form a first module built-up layer routing circuitry 334. The first module built-up layer routing circuitry 334 is generally formed by vias 336 and lines 338. The first module built-up layer routing circuitry 334 generally terminates at a contact pad exposed on the first face 262 of the inner substrate module 242 that is used to connect with the first built-up layer routing circuitry 234 of the first built-up layer 218.

The module core 246 generally includes a cavity 282 in which the IC devices 232 are disposed. Additionally, a plurality of vias 258 are formed through the module core 246. The vias 258 connect with the first module built-up layer routing circuitry 252 to the second module built-up layer routing circuitry 254.

The IC device 232 is a pre-fabricated unitary component that is inserted into the cavity 282 of the module core 246, such as in the form of a chiplet. The IC device 232 has a first face and a second face. The first face of the IC device 232 faces the first module built-up layer 244 of the inner substrate module 242. The second face of the IC device 232 faces the second module built-up layer 248 of the inner substrate module 242. Optionally, the IC device 232 may be utilized flipped upside down. At least one of the faces of the IC device 232 includes contact pads for establishing electrical connection with the internal routing circuitry of the substrate 200. If communication with the internal circuitry of the IC device 232 is only desired from the side of the IC device 232 facing the first module built-up layer 244, then contact pads are only needed on the first face of the IC device 232. Similarly, if communication with the internal circuitry of the IC device 232 is only desired from the side of the IC device 232 facing the second module built-up layer 248, then contact pads are only needed on the second face of the IC device 232. If communication with the internal circuitry of the IC device 232 is desired from both sides of the IC device 232 that the first and second module built-up layers 244, 248, then contact pads are present on both the first and second faces of the IC device 232.

The IC device 232 may be configured as either an active device or a passive device. The active device is a small, specialized, and independent integrated circuit chiplet designed to perform a specific function, such as processing, memory, or I/O. The active device has circuitry configured to perform as an integrated voltage regulator (IVR), an amplifier, or logic transistors, among others. The passive device has circuitry configured to perform as capacitors, inductors, resistors, and the like. The inductors may be air core inductors, magnetic core inductors, or other type of inductor.

In the example depicted in FIG. 3, the IC devices 232 embedded in the module core 246 of the inner substrate module 242 include at least one active device and at least one passive device. The active device includes IVR circuitry. The passive devices are dispose on either sides of the active device and are configured as inductors or capacitors.

As briefly mentioned above, the IC devices 232 are retained in the cavity 282 by mold compound 280. The mold compound 280 may be an epoxy, polyurethane, silicone, or other suitable potting compound. In one example the mold compound 280 is selected to have good thermal conductivity (i.e., thermal conductivity greater than about 1.0 W/m·K) such that heat is readily passed out of the IC device 232. For example, the mold compound 280 may be a thermally conductive epoxy, thermally conductive polyurethane, or thermally conductive silicon. Thermally conductive mold compounds 280 may include aluminum oxide, boron nitride or other material that increases the thermal conductivity above the base compound.

The mold compound 280 includes a first face 310 and a second face 312. The second face 304 of the first module built-up layer 244 is disposed on the first face 310 of the mold compound 280 and the first face 306 of the module core 246. The second face 314 of the second module built-up layer 248 is in contact with the second face 312 of the mold compound 280 and the second face 308 of the module core 246.

To further enhance heat transfer away from the IC devices 232 and out of the module core 246 of the inner substrate module 242, one or more thermally conductive pillars 260 may be disposed through the mold compound 280. The pillar 260 may be formed from copper or other thermally conductive material, such as other metals or carbon-based materials. The pillar 260 may be part of a thermal via. The thermal via includes a via stack formed through the first module built-up layer 244, for example using the vias and lines of the first module built-up layer routing circuitry 252. Although only two pillars 260 configured as thermal vias is illustrated in FIG. 3, it is contemplated that the inner substrate module 242 may include multiple pillars 260 configured as thermal vias to enhance heat transfer away from the IC devices 232, thus ensuring the performance and reliability of the IC devices 232. In one example, the pillar 260 are electrically floating, and not connected to other signal or power carrying circuitry.

The second module built-up layer 248 of the inner substrate module 242 includes a first face 314 and a second face 316. The first face 314 of the second module built-up layer 248 connects the second face 214 of the second built-up layer 222. The second face 316 of the second module built-up layer 248 is in contact with a first face 320 of the filler layer 250.

The second module built-up layer 248 generally includes patterned metal layers formed between dielectric layers 390. Although the dielectric layers 390 are illustrated in FIG. 3 as a single block of material, at least 2 or more layers of dielectric material comprise the dielectric layers 390 of the second module built-up layer 248. The patterned metal layers are interconnected to form a second module built-up layer routing circuitry 384. The second module built-up layer routing circuitry 384 is generally formed by vias 386 and lines 288. The second module built-up layer routing circuitry 384 generally terminates at the contact pads of the IC devices 232 and the vias 258, and optionally also the pillars 260.

The filler layer 250 of the inner substrate module 242 includes the first face 320 and a second face 322. The first face 320 of the filler layer 250 connects to the second face 316 of the second module built-up layer 248. The second face 322 of the filler layer 250 is in contact with a first face 312 of the second built-up layer 222 (as shown in FIG. 2).

Continuing to refer to FIG. 3, the filler layer 250 generally includes patterned metal layers formed between dielectric layers 356. Although the dielectric layers 356 are illustrated in FIG. 3 as a single block of material, at least 2 or more layers of dielectric material comprise the dielectric layers 356 of the filler layer 250. In one example, the dielectric layers 356 of the filler layer 250 are formed from prepreg layers. The patterned metal layers are interconnected to form the filler layer routing circuitry 256. The filler layer routing circuitry 256 is generally formed by vias 352 and lines 354. The filler layer routing circuitry 256 generally connects the second module built-up layer routing circuitry 384 of the inner substrate module 242 with the second built-up layer routing circuitry 284 of the second built-up layer 222 of the substrate 200.

As illustrated in FIG. 3, the filler layer 250 are formed on only one side of the module core 246. This results in the IC devices 232 embedded in the module core 246 being located closer to the first face 262 of the inner substrate module 242 than the second face 264 of the inner substrate module 242. The asymmetrical location of the IC devices within the inner substrate module 242 and consequently within the overall substrate 200 results in improved performance due to the short electrical connections between the IC devices 232 and the IC dies later mounted on the first face 224 of the substrate 200.

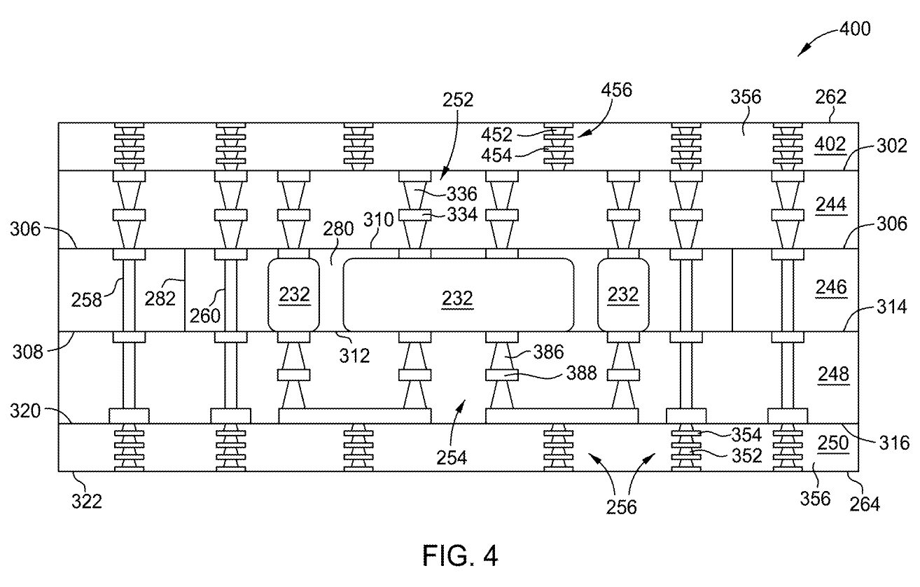

Alternatively, the IC devices 232 and the module core 246 may be located closer to the second face 264 of the inner substrate module 242 or centered within the inner substrate module 242. For example, FIG. 4 depicts an inner substrate module 400 that may be utilized in the substrate 200 in place of the inner substrate module 242. The inner substrate module 400 is essentially the same as inner substrate module 242, except that a second filler layer 402 is disposed on the first face 302 of the first module built-up layer 244.

The second filler layer 402 of the inner substrate module 400 includes a first face 404 and a second face 406. The first face 404 of the filler layer 402 forms the first face 262 of the inner substrate module 400. The second face 406 of the filler layer 402 is in contact with the first face 262 of the first module built-up layer 244.

The second filler layer 402 generally includes patterned metal layers formed between dielectric layers 356. Although the dielectric layers 356 are illustrated in FIG. 4 as a single block of material, at least 2 or more layers of dielectric material comprise the dielectric layers 356 of the second filler layer 402. In one example, the dielectric layers 356 of the second filler layer 402 are formed from prepreg layers. The patterned metal layers are interconnected to form the second filler layer routing circuitry 456. The second filler layer routing circuitry 456 is generally formed by vias 452 and lines 454. The second filler layer routing circuitry 456 generally connects the first module built-up layer routing circuitry 252 of the inner substrate module 400 with the first built-up layer routing circuitry 234 of the first built-up layer 218 of the substrate 200.

FIG. 5 is a schematic sectional view of one example of an electronic device 550 that includes a chip package 500 having substate-in-substrate architecture. The chip package 500 includes a substrate 200 that has a module core embedded in a main core. The substrate 200 may be configured as the described above, or similar substrate having an inner substrate module disposed in a main core and containing has one or more integrated circuit (IC) devices 232 embedded therein. The inner substrate module of the substrate 200 may be configured as either of the inner substrate modules 242, 400 described above, or other similarly constructed module having an IC devices 232 embedded in a core.

The electronic device 550 includes the chip package 500 mounted on a printed circuit board (PCB) 546. The chip package 500 may be mounted on a PCB 546 using a socket, wire bonding, solder balls, or other suitable technique. In the example illustrated in FIG. 5, the chip package 500 electrically and mechanically coupled to the PCB 546 using solder balls 548.

The chip package 500 includes one or more IC dies 502 disposed on the substrate 200. Although only one IC die 502 is illustrated in FIG. 5, one or more IC dies maybe vertically stacked one on top of the other, and/or laterally stacked side-by-side on the core-in-core substrate 200.

The body 506 of the IC die 502 includes a first face 508 and a second face 510. The body 506 of the IC die 502 includes functional circuitry 514. The functional circuitry 514 is disposed within the body 506 of the IC die 502 and may include memory, compute and/or logic circuitry. In one example, the functional circuitry 514 is configured as a processor, such as a central processing unit (CPU) or a graphics processing unit (GPU). The functional circuitry 514 terminates at a contact pad 512 exposed on the second face 510 that faces the substrate 200.

The second face 510 of the IC die 502 is electrically and mechanically coupled to the substrate 200. In one example, interconnects 516 couple the contact pads 512 exposed on the second face 510 of the IC die 502 to the first built-up layer routing circuitry 234 of the substrate 200. The interconnects 516 may be solder balls, or alternatively, the interconnects maybe a hybrid bonding layer formed on the substrate 200.

The second built-up layer routing circuitry 284 terminates at a contact pad 592 exposed on the second face 226 of the substrate 200. In one example, a solder ball 548 is utilized to connect the contact pad 592 of the substrate 200 with a contact pad of the PCB 546, thus forming the electronic device 550 and electrically connecting the functional circuitry 514 of the IC die 502 (and/or circuit elements of the IC device 532) to the circuitry of the PCB 546.

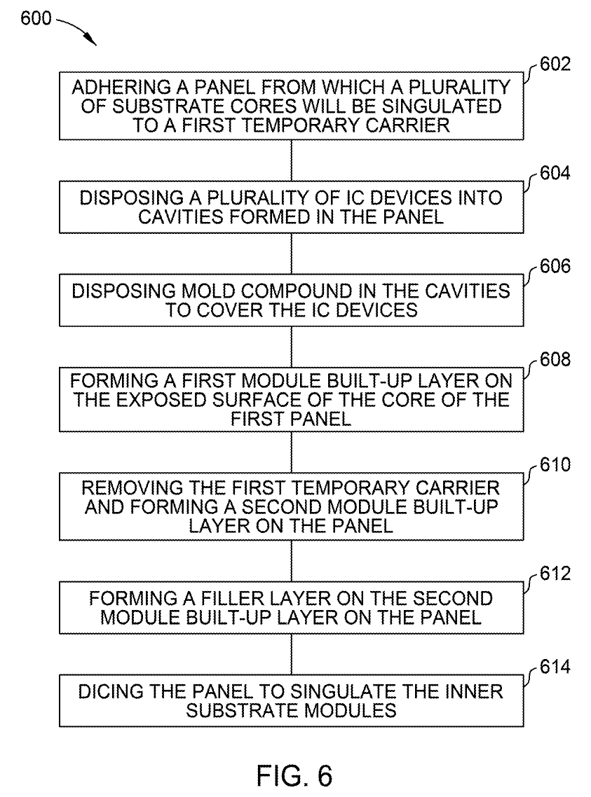

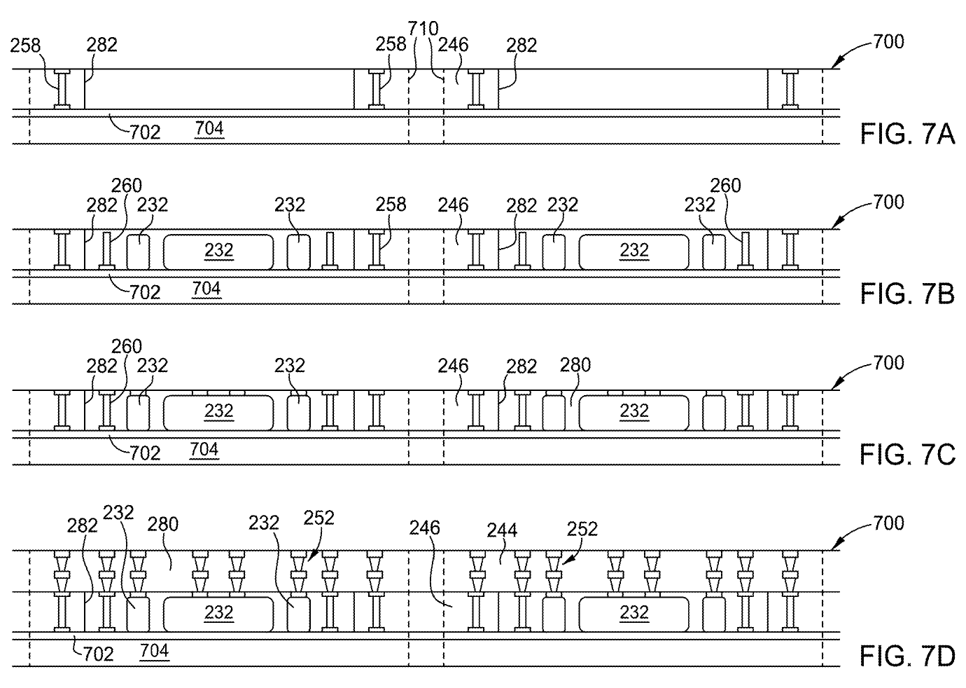

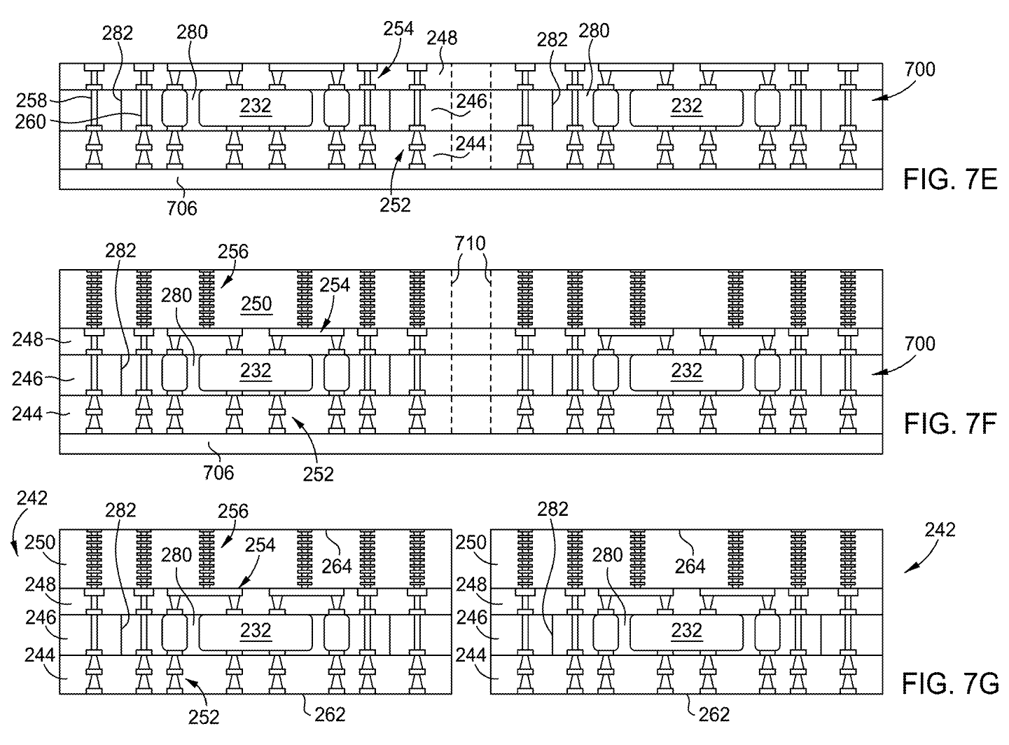

FIG. 6 is a block diagram of one example of method 600 for forming an inner substrate module, such as the inner substrate module 242 described above. FIGS. 7A-7G are schematic sectional views of the inner substrate module 242 during different stages of fabrication in accordance with the method 600. Although the method 600 describes fabricating an asymmetrical structure having the IC devices 232 offset towards the first face 262 of the substrate 200, the method 600 may be adapted to fabricate symmetrical structures that have the IC devices 232 disposed approximately in the middle of the substrate 200.

The method 600 begins at operation 602 by adhering a panel 700 from which a plurality of substrate cores 246 will be singulated to a first temporary carrier 704, as illustrated in FIG. 7A. The first temporary carrier 704 may be an aluminum or plastic palette, or other structure having a flat surface on which the panel 700 is secured. The first temporary carrier 704 may include one or more prepreg layers 702 disposed between the carrier 704 and the panel 700. The panel 700 includes a plurality of cavities 282. The panel may additionally include a plurality of vias 258 formed laterally outward of the cavities 282. Scribe lanes 710 are illustrated in phantom between the cavities 282 illustrating where the individual cores 246 will be later singulated.

At operation 604, a plurality of IC devices 232 are disposed in the cavities 282, as illustrated in FIG. 7B. The IC devices 232 may be active or passive devices. In FIG. 7B, two passive IC devices 232 are disposed in the cavity 282 on either side of an active IC device 232. The IC devices 232 may be secured to the prepreg layer 702 or the first temporary carrier 702 using die attached tape or other temporary adhesive. Contact pads are also formed on the IC devices 232 at operation 604.

Optionally at operation 604, pillars 260 may be formed in the cavities 282. The pillars 260 may be formed by plating or other suitable technique.

At operation 606, mold compound 280 is disposed in the cavities 282 to cover the IC devices 232, as illustrated in FIG. 7C. The mold compound 280 is ground coplanar with the top of the panel such that the contact pads of the IC devices 232 are exposed through the mold compound 280.

At operation 608, a first module built-up layer 244 is formed on the exposed surface of the core 246 of the first panel 700, as illustrated in FIG. 7D. The first module built-up layer 244 includes first module built-up layer routing circuitry 252 that is electrically coupled to the vias 258 formed in the core 246, and the pillars 260 disposed in the cavities 282. The first module built-up layer routing circuitry 252 is also electrically coupled to the IC devices 232 disposed in the cavities 282 of the panel 700.

The first module built-up layer 244 is formed by patterning metal layers disposed between dielectric layers. The patterned metal layers form the first module built-up layer routing circuitry 252. The first module built-up layer routing circuitry 252 is formed by connected lines and vias formed from the patterned metal layers of the first module built-up layer routing circuitry 252.

At operation 610, the first temporary carrier 704 is removed, and a second module built-up layer 248 is formed on the panel 700, as illustrated in FIG. 7E. At operation 610, a second temporary carrier 706 may be coupled to the panel 700.

The second module built-up layer 248 includes second module built-up layer routing circuitry 254 that is electrically coupled to the vias 258 formed in the core 246, and optionally to the pillars 260 disposed in the cavities 282. The second module built-up layer routing circuitry 254 is also electrically coupled to the IC devices 232 disposed in the cavities 282 of the panel 700.

The second module built-up layer 248 is formed by patterning metal layers disposed between dielectric layers. The patterned metal layers form the second module built-up layer routing circuitry 254. The second module built-up layer routing circuitry 254 is formed by connected lines and vias formed from the patterned metal layers of the first module built-up layer routing circuitry 252.

At operation 612, a filler layer 250 is formed on the second module built-up layer 248 is formed on the panel 700, as illustrated in FIG. 7F. At or after operation 612, the second temporary carrier 706 is removed.

The filler layer 250 includes filler layer routing circuitry 256 that is electrically coupled to the second module built-up layer routing circuitry 254. The filler layer routing circuitry 256 is formed by patterning metal layers disposed between dielectric layers. In one example, the dielectric layers are prepreg layers. The patterned metal layers form the filler layer routing circuitry 256. The filler layer routing circuitry 256 is formed by connected lines and vias formed from the patterned metal layers of the filler layer routing circuitry 256.

At operation 614, the panel 700 is diced to singulate the inner substrate modules 242, as illustrated in FIG. 7G. The inner substrate modules 242 may be singulated using a wire saw or using another suitable technique. Optionally, the second temporary carrier 706 may be removed after singulation.

Optionally between operations 612 and 614, the inner substrate modules 242 still cojoined in the panel 700 may be tested. Testing the inner substrate modules 242 prior to singulation improves efficiency and also allows defected inner substrate modules 242 to be discarded prior to incorporation into more expensive devices.

The method 600 may alternatively be used to form a plurality of inner substrate modules 400. When fabricating the inner substrate modules 400, a first filler layer is formed on the first module built-up layer 244 as part of operation 608, prior to the second filler layer being formed at operation 612.

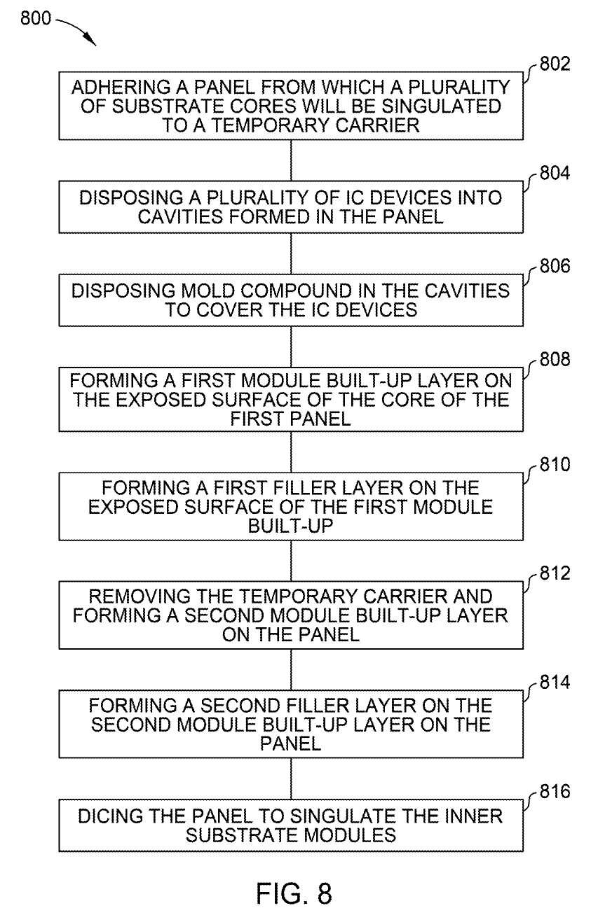

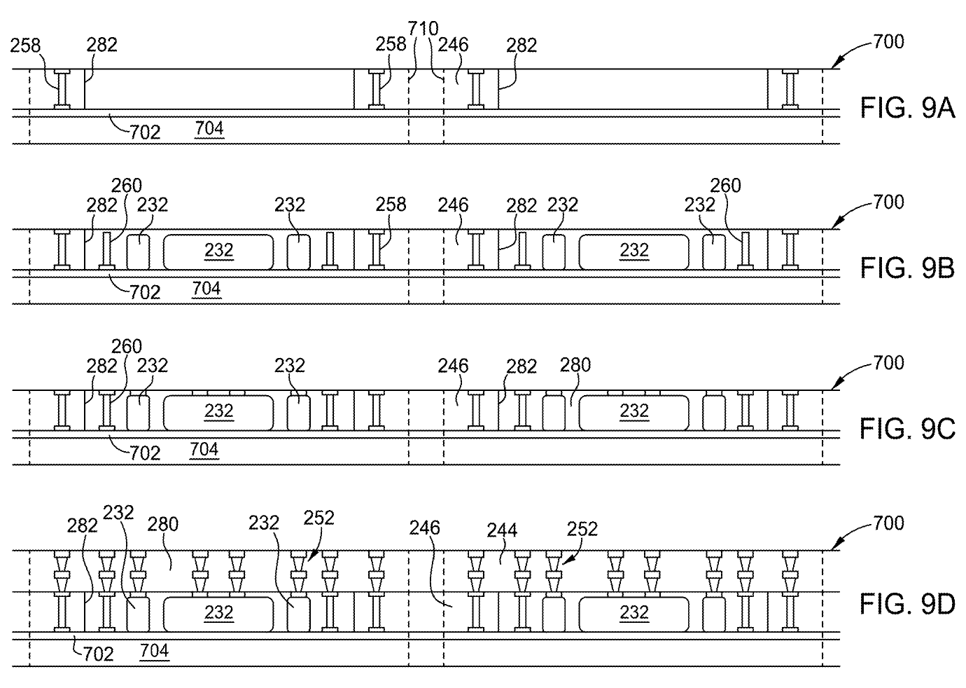

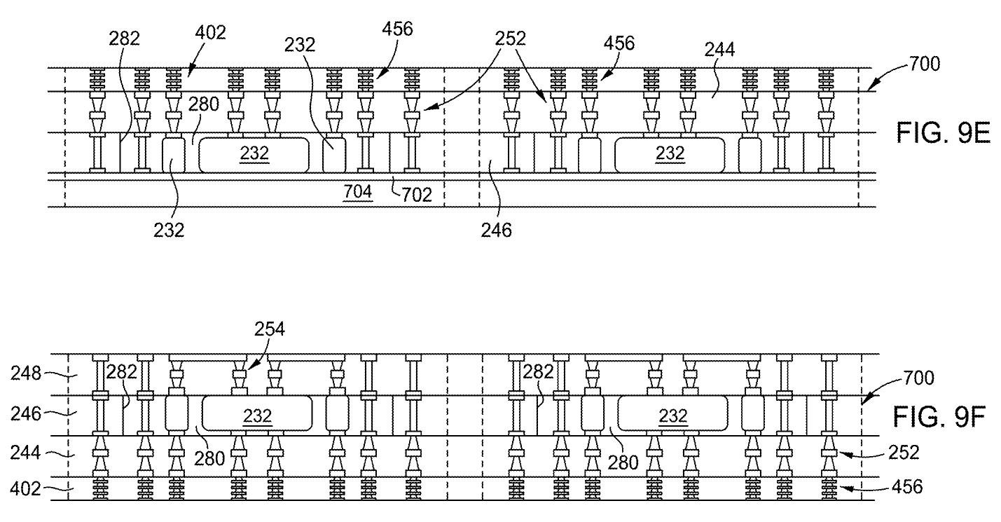

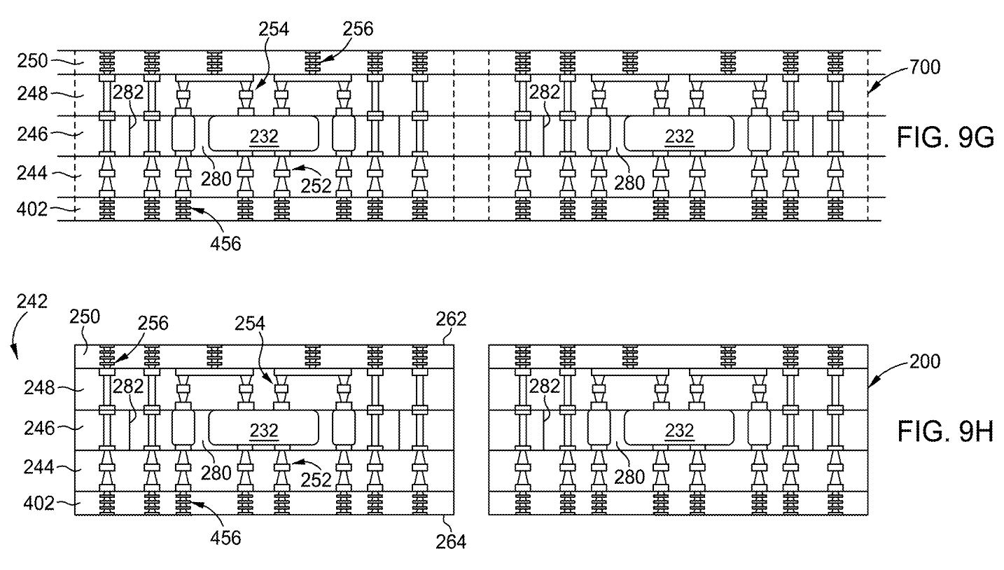

FIG. 8 is a block diagram of one example of method 800 for forming an inner substrate module, such as the inner substrate module 242 described above. FIGS. 9A-9G are schematic sectional views of the inner substrate module 242 during different stages of fabrication in accordance with the method 800. Although the method 800 describes fabricating a symmetrical structure having the IC devices 232 disposed approximately in the middle of the substrate 200, the method 800 may be adapted to fabricate asymmetrical structures that have the IC devices 232 offset towards one of the first or second faces 262, 264 of the substrate 200.

The method 800 begins at operation 802 by adhering a panel 700 from which a plurality of substrate cores 246 will be singulated to a temporary carrier 704, as illustrated in FIG. 9A. The temporary carrier 704 may be an aluminum or plastic palette, or other structure having a flat surface on which the panel 700 is secured. The first carrier 704 may include one or more prepreg layers 702 disposed between the carrier 704 and the panel 700. The panel 700 includes a plurality of cavities 282. The panel may additionally include a plurality of vias 258 formed laterally outward of the cavities 282. Scribe lanes 410 are illustrated in phantom between the cavities 282 illustrating where the individual cores 246 will be later singulated.

At operation 804, a plurality of IC devices 232 are disposed in the cavities 282, as illustrated in FIG. 9B. The IC devices 232 may be active or passive devices. In FIG. 9B, two passive IC devices 232 are disposed in the cavity 282 on either side of an active IC device 232. The IC devices 232 may be secured to the prepreg layer 902 or the first temporary carrier 902 using die attached tape or other temporary adhesive. Contact pads are also formed on the IC devices 232 at operation 804.

Optionally at operation 804, pillars 260 may be formed in the cavities 282. The pillars 260 may be formed by plating or other suitable technique.

At operation 806, mold compound 280 is disposed in the cavities 282 to cover the IC devices 232, as illustrated in FIG. 9C. The mold compound 280 is ground coplanar with the top of the panel such that the contact pads of the IC devices 232 are exposed through the mold compound 280.

At operation 808, a first module built-up layer 244 is formed on the exposed surface of the core 246 of the first panel 700, as illustrated in FIG. 9D. The first module built-up layer 244 includes first module built-up layer routing circuitry 252 that is electrically coupled to the vias 258 formed in the core 246, and the pillars 260 disposed in the cavities 282. The first module built-up layer routing circuitry 252 is also electrically coupled to the IC devices 232 disposed in the cavities 282 of the panel 700.

The first module built-up layer 244 is formed by patterning metal layers disposed between dielectric layers. The patterned metal layers form the first module built-up layer routing circuitry 252. The first module built-up layer routing circuitry 252 is formed by connected lines and vias formed from the patterned metal layers of the first module built-up layer routing circuitry 252.

At operation 810, a first filler layer 402 is formed on the second module built-up layer 248 is formed on the panel 700, as illustrated in FIG. 9E. At or after operation 810, the second temporary carrier 906 is removed.

The first filler layer 402 includes filler layer routing circuitry 456 that is electrically coupled to the first module built-up layer routing circuitry 252. The filler layer routing circuitry 456 is formed by patterning metal layers disposed between dielectric layers. In one example, the dielectric layers are prepreg layers. The patterned metal layers form the filler layer routing circuitry 456. The filler layer routing circuitry 456 is formed by connected lines and vias formed from the patterned metal layers of the filler layer routing circuitry 456.

At operation 812, the temporary carrier 704 is removed, and a second module built-up layer 248 is formed on the panel 700, as illustrated in FIG. 9F. At operation 812, a second temporary carrier may optionally be coupled to the panel 700.

The second module built-up layer 248 includes second module built-up layer routing circuitry 254 that is electrically coupled to the vias 258 formed in the core 246, and optionally to the pillars 260 disposed in the cavities 282. The second module built-up layer routing circuitry 254 is also electrically coupled to the IC devices 232 disposed in the cavities 282 of the panel 700.

The second module built-up layer 248 is formed by patterning metal layers disposed between dielectric layers. The patterned metal layers form the second module built-up layer routing circuitry 254. The second module built-up layer routing circuitry 254 is formed by connected lines and vias formed from the patterned metal layers of the first module built-up layer routing circuitry 252.

At operation 814, a second filler layer 250 is formed on the second module built-up layer 248 is formed on the panel 700, as illustrated in FIG. 9G. At or after operation 814, the second temporary carrier, if present, is removed.

The second filler layer 250 includes filler layer routing circuitry 256 that is electrically coupled to the second module built-up layer routing circuitry 254. The filler layer routing circuitry 256 is formed by patterning metal layers disposed between dielectric layers. In one example, the dielectric layers are prepreg layers. The patterned metal layers form the filler layer routing circuitry 256. The filler layer routing circuitry 256 is formed by connected lines and vias formed from the patterned metal layers of the filler layer routing circuitry 256.

At operation 816, the panel 700 is diced to singulate the inner substrate modules 242, as illustrated in FIG. 9H. The inner substrate modules 242 may be singulated using a wire saw or using another suitable technique. Optionally, the second temporary carrier 906 may be removed after singulation.

Optionally between operations 812 and 814, the inner substrate modules 242 still cojoined in the panel 700 may be tested. Testing the inner substrate modules 242 prior to singulation improves efficiency and also allows defected inner substrate modules 242 to be discarded prior to incorporation into more expensive devices.

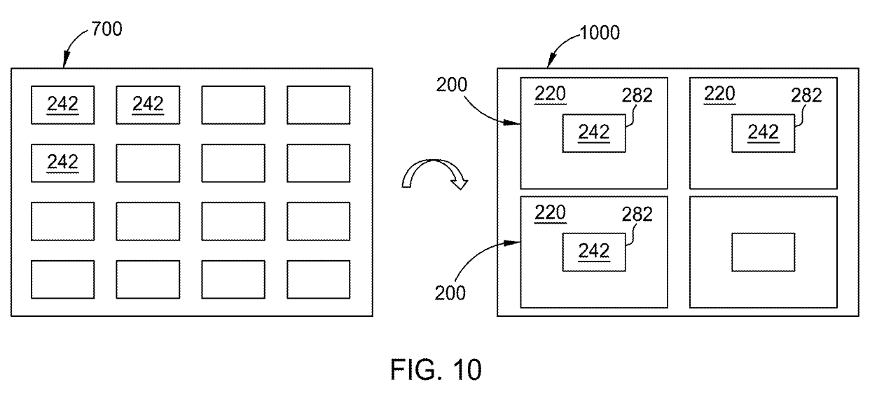

FIG. 10 is a high level schematic diagram of one example of a method for forming substrate-in-substrate structures. Depicted in FIG. 10 is a first panel 700 that includes a plurality of inner substrate modules 242 prior to singulation. Alternatively, the first panel 700 may include a plurality of inner substrate modules 400 or other inner substrate having one or one or more IC devices 232 to singulation. As described above, each inner substrate module 242 includes one or more IC devices 232. Prior to dicing the first panel 700, the inner substrate modules 242 are tested. After testing, the first panel 700 is diced to separate the individual inner substrate modules 242. The inner substrate modules 242 are then disposed in cavities 282 formed in a second panel 1000.

The second panel 1000 is fabricated from the material that will form the main core 220 of the substrate 200 after the panel 1000 is diced. The inner substrate modules 242 may be retained in the cavities 282 using an adhesive (280, shown in FIG. 2). After embedding the inner substrate modules 242 in the cavities 282, the second panel 1000 is diced to separate the individual substrates 200.

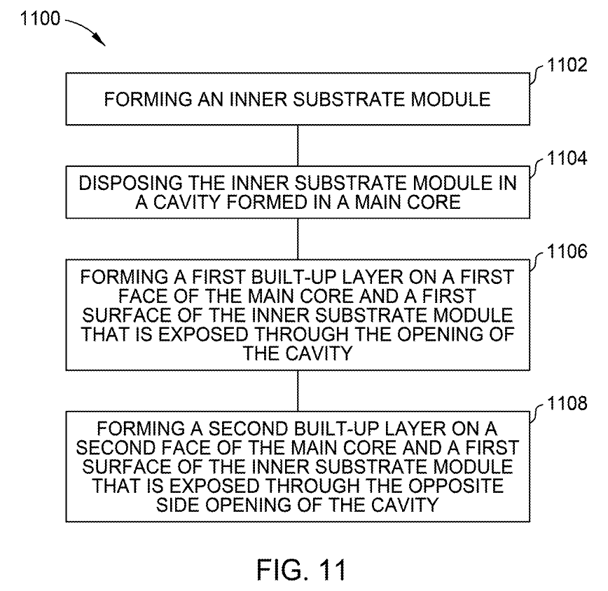

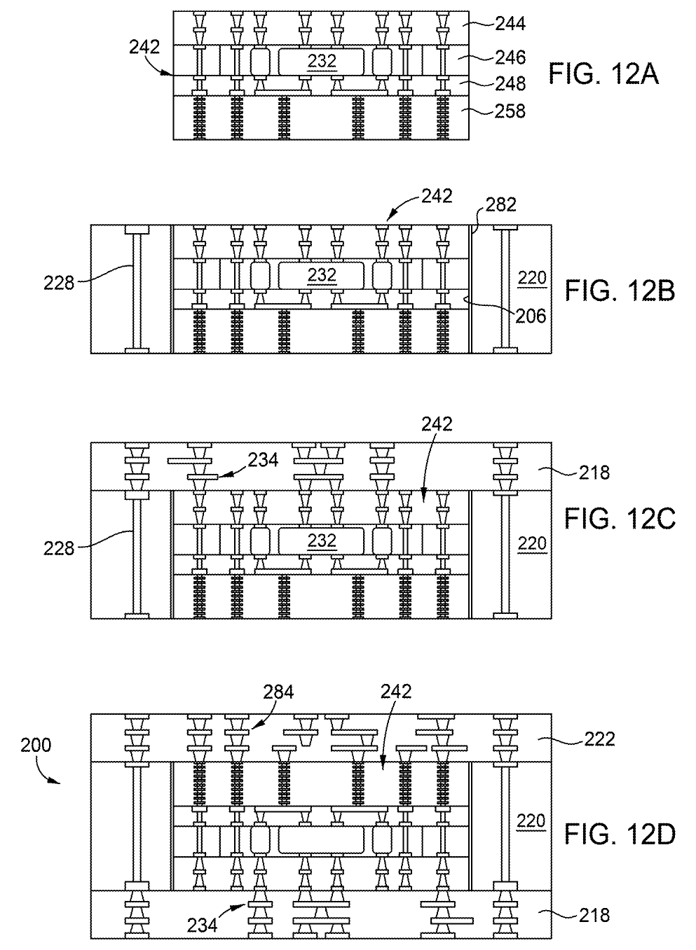

FIG. 11 is a block diagram of one example of a method 1100 for forming a substrate 200 having an inner substrate module embedded in a main core 220. The inner substrate module may be configured as either of the inner substrate modules 242, 400 described above, or other substrate module having a core with embedded IC devices 232 that can be disposed in a larger, main core 220. FIGS. 12A-12D are schematic sectional views of the substrate 200 during different stages of fabrication.

The method 1100 begins at operation 1102 by forming an inner substrate module 242, as illustrated in FIG. 12A. An inner substrate module 400 or other suitable substrate module having a core with embedded IC devices 232 may be used as an alternative to the inner substrate module 242. The inner substrate module 242 may be fabricated by any suitable technique, such as but not limited to, the method 600 described above.

At operation 1104, the inner substrate module 242 is disposed in a cavity 282 formed in a main core 220, as illustrated in FIG. 12B. Although not shown in FIG. 12B, the cavity 282 may be one of a plurality of cavities 282 formed in a panel, such as but not limited to the panel 1000 described above with reference to FIG. 10. The inner substrate module 242 may be secured in the cavity 282 using an adhesive 216.

At operation 1106, a first built-up layer 218 is formed on a first face of the main core 220 and a first surface of the inner substrate module 242 that is exposed through the opening of the cavity 282, as illustrated in FIG. 12C. The first built-up layer 218 may be formed as described above.

At operation 1108, a second built-up layer 222 is formed on a second face of the main core 220 and a second surface of the inner substrate module 242 that is exposed through the opposite side opening of the cavity 282, as illustrated in FIG. 12D.

The second built-up layer 222 may be formed as described above. At operation 1108, the panel 1000 is diced to release the individual substrates 200, one of which is illustrated in FIG. 12D.

Thus, a substrate-in-substrate architecture has been disclosed above that beneficially reduces the overall layer count for substrate as compared to conventional designs, which results in yield improvement, complexity reduction, cost reduction, and capacity use reduction. Additionally, testing the IC device module fabricated in the inner substrate module prior to insertion in the outer main core provides additional yield improvements.

The substrate-in-substrate architecture also includes features that enhance the functionality and versatility of advanced computing substrates. These include asymmetric stack-up capability, dual-module integration, comprehensive pre-embedding testing, and full vertical connectivity. These features collectively provide a robust and flexible approach to addressing the challenges of modern electronic component integration, resulting in improved performance and reliability of advanced computing systems.

The substrate-in-substrate architecture effectively bridges the gap between component thickness and substrate core thickness, ensuring reliable connections on both sides of embedded components. IC device embedding in smaller body sizes significantly improves yield and allows for greater capacity and flexibility with alternative suppliers. Precise component-module thickness control and pad location accuracy enable fan-out during module built-up, which allows new pad sizes and enhanced line/space (L/S) control for interconnections. The additional inner substrate module test prior to embedding into the main substrate increase production yields and reduces the probability that assembled components will be scrapped. Furthermore, separating module substrate and primary substrate build-up processes allows for increase factory capacity and reduced production costs.

The substrate-in-substrate architecture also may be fabricated in a symmetrical manner, that is with the inner substrate vertically centered within the outer substrate. In one example, component embedding done on separate substrate, use built-up process for increasing thickness and/or fanning out, and then singulated in module form before being placed into primary substrate for thick core embedding. Bridges gap between component thickness and substrate core thickness, especially when forming two-sided connection to embedded components. Components, such as IC devices, can be embedded in the inner substrate module which as a much smaller body size, which dramatically improves yield. Component-module also has tighter thickness control and pad location accuracy, resulting in improved reliability.

Fanning out during module built-up, which enables new pad size from component pads to built-up pads & enables tighter L/S control for on-module when forming connections between components. A second test insertion point is provided for inner substrate module (after already forming component connections) before embedding into primary main substrate, which improves yield. Additionally, capacity is increased with module substrate built-up separately from primary substrate built-up.

ESD is mitigated by attaching components on B-stage, thus enhancing package reliability. Power delivery optimization is also enabled using the asymmetric stack design that allows active silicon components to be positioned closer to the IC die, optimizing power delivery and overall performance.

This innovative process addresses critical challenges in component embedding and packaging by improving reliability, yield, and performance while offering enhanced flexibility and capacity.

The substrate-in-substrate architecture also provides a method to bridge gap between component thickness and substrate core thickness. The adaptive layered package architecture enables the substrate core and component thickness to be matched for two-sided connections without adding prepreg layers to increase effective core thickness.

Modules can be embedded in single tile or panel, resulting in lower EMB cost and better throughput at primary substrate process. Moreover, thickness control is enhanced (substrate-like module +/-10um vs individual components +/- 20um), which consequently results in better plating/filling performance and process yields.

Additionally, fan out constraints are beneficially eased, as pad size can be adjusted as needed from component pads to built-up pads. This again helps to reduce via to pad shift fail mode when placing components in cavity and therefore higher yields. Moreover, L/S rules used to connect components in module are decoupled from L/S required by primary substrate stack up, thus providing improved design flexibility. Component pitch can be adjusted by fanning out in module substrate to match preferred pitch in primary substrate. Additionally, alignment to substrate module pads will also have better margin than alignment to component pads due to the substrate pad location accuracy defined by lithography. Costs are improved as component embedding cost scales with cavity perimeter length.

The disclosed technology may also be described by one or more of the following non-limiting examples.

Example 1. An integrated circuit (IC) module including: a substrate core having a first face, a second face, and a cavity formed in the substrate core and open through the first and second faces of the substrate core; an IC device module disposed in the cavity, the IC device module including: one or more IC devices; upper module built-up layers having circuitry coupled to the one or more IC devices; and lower module built-up layers having circuitry coupled to the one or more IC devices and separated from the upper module built-up layers by the plurality of IC devices; upper built-up layers formed on the IC device module and the first face of the substrate core, the upper built-up layers having circuitry coupled to the upper module built-up layers and circuitry routed through the substrate core; and lower built-up layers formed on the IC device module and the second face of the substrate core, the lower built-up layers having circuitry coupled to the lower module built-up layers and the circuitry routed through the substrate core.

Example 2. The IC module according to Example 1, wherein the IC device module is located closer to the first face of the substrate core than the second face of the substrate core.

Example 3. The IC module according to Example 1, further including: a gap filling material disposed in the cavity between the IC device module and substrate core.

Example 4. The IC module according to Example 1, wherein the plurality of devices includes at least one power cell device.

Example 5. The IC module according to Example 4, wherein a first device of the at least one power cell device includes a device selected from the group consisting of a voltage regulator, a capacitor, an inductor, and a resistor.

Example 6. The IC module according to Example 1, wherein the IC device module is a power management module.

Example 7. The IC module according to Example 1, wherein the IC device module includes a voltage regulator.

Example 8. The IC module according to Example 1, wherein the IC device module includes an integrated circuit die.

Example 9. The IC module according to Example 1, further including: a printed circuit board coupled to the lower built-up layers; and an integrated circuit die coupled to the upper built-up layers.

Example 10. The IC module according to Example 1, wherein the IC device module further includes: a module substrate having a thickness less than a thickness of the substrate core, the module substrate disposed between the upper and lower module built-up layers, the module substrate having a through cavity in which the one or more IC devices are disposed.

Example 11. An integrated circuit (IC) module including: (a) a first assembly including: a first substrate core having a first face, a second face, and a cavity formed in the first substrate core and open through the first and second faces of the first substrate core; a first IC device module disposed in the cavity, the first IC device module including: one or more first IC devices; upper module built-up layers having circuitry coupled to the one or more first IC devices; and lower module built-up layers having circuitry coupled to the one or more first IC devices and separated from the upper module built-up layers by the one or more first IC devices; upper built-up layers formed on the first IC device module and the first face of the first substrate core, the upper built-up layers having circuitry coupled to the upper module built-up layers and circuitry routed through the first substrate core; (b) a second assembly including: a second substrate core having a first face, a second face, and a cavity formed in the second substrate core and open through the first and second faces of the second substrate core; a second IC device module disposed in the cavity, the second IC device module including: one or more second IC devices; upper module built-up layers having circuitry coupled to the one or more second IC devices; and lower module built-up layers having circuitry coupled to the one or more second IC devices and separated from the upper module built-up layers by the one or more second IC devices; upper built-up layers formed on the second IC device module and the first face of the second substrate core, the upper built-up layers having circuitry coupled to the upper module built-up layers and circuitry routed through the second substrate core; and (c) a sacrificial carrier having the first assembly disposed on a first side and the second assembly disposed on a second side that faces away from the first side.

Example 12. A method for fabricating an integrated circuit (IC) module, the method including: mounting one or more first IC devices in a cavity formed through a first substrate core; forming upper module built-up layers having circuitry coupled to the one or more first IC devices; forming lower module built-up layers having circuitry coupled to the one or more first IC devices, the lower module built-up layers separated from the upper module built-up layers by the one or more first IC devices; mounting the first substrate core in a cavity formed through a second substrate core; and forming upper built-up layers formed on the upper module built-up layers and the second surface core.

Example 13. The method according to Example 12 further including: mounting an IC die on the upper built-up layers.

Example 14. The method according to Example 13 further including: forming lower built-up layers formed on the lower module built-up layers and the second surface core and mounting the lower built-up layers and the second surface core on a printed circuit board.

Example 15. The method according to Example 12, wherein forming lower module built-up layers further includes: forming more layers than layers formed when forming the upper module built-up layers.

Example 16. The method according to Example 12 further including: mounting one or more second IC devices in a cavity formed through a second substrate core, the second substrate core separated from the first substrate core by a sacrificial substrate; forming second upper module built-up layers having circuitry coupled to the one or more second IC devices; and forming second lower module built-up layers having circuitry coupled to the one or more second IC devices, the second lower module built-up layers separated from the second upper module built-up layers by the one or more second IC devices.

Example 17. An integrated circuit (IC) substrate including: a main core having a first face, a second face, and a main core cavity, the main core cavity open through the first and second faces of the main core; an IC device module disposed in the main core cavity, the IC device module including: a module core having a module cavity, the module core having a thickness that is less than a thickness of the main core; and one or more IC devices disposed in the module cavity; and first built-up layers formed on the IC device module and the first face of the main core, the first built-up layers having circuitry coupled to circuitry of the one or more IC devices.

Example 18. The IC substrate of Example 17, wherein the IC device module further includes first module built-up layers disposed in the main core cavity between the first built-up layers and the one or more IC devices, the first module built-up layers having circuitry connecting the circuitry of the first built-up layers to the circuitry of the one or more IC devices.

Example 19. The IC substrate of Example 18, wherein the IC device module further includes: second module built-up layers disposed in the main core cavity, the one or more IC devices separating the second module built-up layers from the first module built-up layers, the second module built-up layers having circuitry connecting the circuitry of the first built-up layers and/or the circuitry of the one or more IC devices.

Example 20. The IC substrate of Example 19, wherein the IC device module further includes: first filler layers disposed in the main core cavity and in contact with the second module built-up layers, the first filler layers having circuitry connecting the circuitry of the second built-up layers.

Example 21. The IC substrate of Example 20, wherein the IC device module is disposed closer to the first face of the main core relative to the second face of the main core.

Example 22. The IC substrate of Example 20, wherein the IC device module further includes: second filler layers disposed in the main core cavity and in contact with the first module built-up layers, the second filler layers having circuitry connecting the circuitry of the first built-up layers.

Example 23. The IC substrate of Example 17 further including: second built-up layers disposed on the IC device module and the second face of the main core, the second built-up layers having circuitry connected to circuitry of the one or more IC devices.

Example 24. The IC substrate of Example 17, wherein the wherein the one or more IC devices are disposed closer to the first face of the main core relative to the second face of the main core.

Example 25. The IC substrate of Example 17, further including: an adhesive securing the IC device module within the cavity of the main core.

Example 26. The IC substrate of Example 17, wherein the one or more IC devices includes at least one power cell device.

Example 27. The IC substrate of Example 26, wherein a first device of the at least one power cell device includes a device selected from the group consisting of a voltage regulator, a capacitor, an inductor, and a resistor.

Example 28. The IC substrate of Example 17, wherein the one or more IC devices includes a power management module.

Example 29. The IC substrate of Example 17, wherein the one or more IC devices includes a voltage regulator.

Example 30. The IC substrate of Example 17, wherein the thickness of the module core is less than or equal to about 750 µm, and the thickness of the main core is greater than about 1000 µm.

Example 31. A chip package including: a main core having a first face, a second face, and a main core cavity, the main core cavity open through the first and second faces of the main core; an IC device module disposed in the main core cavity, the IC device module including: a module core having a module cavity, the module core having a thickness that is less than a thickness of the main core; and one or more IC devices embedded in mold compound filling in the module cavity; first built-up layers formed on the IC device module and the first face of the main core; and an integrated circuit (IC) die disposed on the first built-up layers, the IC die having functional circuitry coupled to the one or more IC devices through the first built-up layer routing circuitry.

Example 32. The chip package of Example 31, wherein the thickness of the module core is less than or equal to about 750 µm, and the thickness of the main core is greater than about 1000 µm.

Example 33. The chip package of Example 31, wherein the IC device module is disposed closer to the first face of the main core relative to the second face of the main core.

Example 34. The chip package of Example 31, wherein the IC device module further includes. electrically floating pillars extending through the mold compound.

Example 35. A chip package including: a main core having a first face, a second face, and a main core cavity, the main core cavity open through the first and second faces of the main core, the main core having a thickness of greater than about 1000 µm; an IC device module disposed in the main core cavity, the IC device module including: a module core having a module cavity, the module core having a thickness that is less than or equal to about 750 µm; one or more IC devices embedded in mold compound filling in the module cavity; first module built-up layers disposed in the main core cavity in and contact with the mold compound; second module built-up layers disposed in the main core cavity and in contact with the mold compound; and first filler layers disposed in the main core cavity and in contact with the second module built-up layers, the first filler layer having first filler layer circuitry coupled to the one or more IC devices through circuitry of the second module built-up layers; first built-up layers formed on the IC device module and the first face of the main core; and an integrated circuit (IC) die disposed on the first built-up layers, the IC die having functional circuitry coupled to the one or more IC devices through circuitry of the first built-up layer.

Example 36. The chip package of Example 35, wherein the one or more IC devices includes an integrated voltage regulators (IVR).

Various features are described hereinafter with reference to the drawing figures. It should be noted that the drawing figures may or may not be drawn to scale and that the elements of similar structures or functions are represented by like reference numerals throughout the drawing figures. It should be noted that the drawing figures are only intended to facilitate the description of the features of the examples. They are not intended as an exhaustive description of the examples below or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described. Referring now to the drawing figures, the details of examples are representative layouts schematically illustrated. Like elements in the drawing figures will be represented by like numbers, and similar elements will be represented by like numbers with a different lower-case letter suffix.

While the foregoing is directed to embodiments of the present invention, other and further embodiments of the invention may be devised without departing from the basic scope thereof, and the scope thereof is determined by the claims that follow.

What is claimed is:

1. An integrated circuit (IC) substrate comprising:
a main core having a first face, a second face, and a main core cavity, the main core cavity open through the first and second faces of the main core;
an IC device module disposed in the main core cavity, the IC device module comprising:
a module core having a module cavity, the module core having a thickness that is less than a thickness of the main core; and
one or more IC devices disposed in the module cavity; and
first built-up layers formed on the IC device module and the first face of the main core, the first built-up layers having circuitry coupled to circuitry of the one or more IC devices.

2. The IC substrate of claim 1, wherein the IC device module further comprises:
first module built-up layers disposed in the main core cavity between the first built-up layers and the one or more IC devices, the first module built-up layers having circuitry connecting the circuitry of the first built-up layers to the circuitry of the one or more IC devices.

3. The IC substrate of claim 2, wherein the IC device module further comprises:
second module built-up layers disposed in the main core cavity, the one or more IC devices separating the second module built-up layers from the first module built-up layers, the second module built-up layers having circuitry connecting the circuitry of the first built-up layers and/or the circuitry of the one or more IC devices.

4. The IC substrate of claim 3, wherein the IC device module further comprises:
first filler layers disposed in the main core cavity and in contact with the second module built-up layers, the first filler layers having circuitry connected to the circuitry of the second built-up layers.

5. The IC substrate of claim 4, wherein the IC device module is disposed closer to the first face of the main core relative to the second face of the main core.

6. The IC substrate of claim 4, wherein the IC device module further comprises:
second filler layers disposed in the main core cavity and in contact with the first module built-up layers, the second filler layers having circuitry connecting the circuitry of the first built-up layers.

7. The IC substrate of claim 1 further comprising:
second built-up layers disposed on the IC device module and the second face of the main core, the second built-up layers having circuitry connected to circuitry of the one or more IC devices.

8. The IC substrate of claim 1, wherein the one or more IC devices are disposed closer to the first face of the main core relative to the second face of the main core.

9. The IC substrate of claim 1, further comprising:
an adhesive securing the IC device module within the main core cavity.

10. The IC substrate of claim 1, wherein the one or more IC devices includes at least one power cell device.

11. The IC substrate of claim 10, wherein a first device of the at least one power cell device comprises a device selected from the group consisting of a voltage regulator, a capacitor, an inductor, and a resistor.

12. The IC substrate of claim 1, wherein the one or more IC devices includes a power management module.

13. The IC substrate of claim 1, wherein the one or more IC devices includes a voltage regulator.

14. The IC substrate of claim 1, wherein the thickness of the module core is less than or equal to about 750 µm, and the thickness of the main core is greater than about 1000 µm.

15. A chip package comprising:
a main core having a first face, a second face, and a main core cavity, the main core cavity open through the first and second faces of the main core;
an IC device module disposed in the main core cavity, the IC device module comprising:
a module core having a module cavity, the module core having a thickness that is less than a thickness of the main core; and
one or more IC devices embedded in mold compound filling in the module cavity;
first built-up layers formed on the IC device module and the first face of the main core; and
an integrated circuit (IC) die disposed on the first built-up layers, the IC die having functional circuitry coupled to the one or more IC devices through circuitry of the first built-up layer.

16. The chip package of claim 15, wherein the thickness of the module core is less than or equal to about 750 µm, and the thickness of the main core is greater than about 1000 µm.

17. The chip package of claim 15, wherein the IC device module is disposed closer to the first face of the main core relative to the second face of the main core.

18. The chip package of claim 15, wherein the IC device module further comprises:
electrically floating pillars extending through the mold compound.

19. A method for forming a package substrate, the method comprising:
disposing an inner substrate module in a cavity formed in a main core, the inner substrate module having IC devices embedded in a cavity of an inner core; and
forming a first built-up layer is formed on a first face of the main core and a first surface of the inner substrate module that is exposed through the opening of the cavity of the main core.

20. The method of claim 19, further comprising:
dicing a panel to release a plurality of individual substrates, one of the released substrates comprising the main core having the first built-up layer disposed thereon and the inner substrate module disposed therein.
